(19) United States
(12) Patent Application Publication
(10) Pub. No.: US 2010/0207273 A1
(43) Pub. Date: Aug. 19, 2010

(54) Micro Ball Feeding Method

(76) Inventor: Kengo Aoya, Oita-ken (JP)

Correspondence Address: TEXAS INSTRUMENTS INCORPORATED, P O BOX 655474, M/S 3999, DALLAS, TX, 75265, US

(21) Appl. No.: 12/598,648

(22) PCT Filed: Jan. 17, 2008
(86) PCT No.: PCT/JP2008/050531

§ 371 Date: Apr. 22, 2010

(30) Foreign Application Priority Data
Jan. 25, 2007 (JP) 2007-015422

(51) Int. Cl. H01L 23/498; H01L 21/3205

(52) U.S. Cl. 257/738; 438/666; 257/E21.294; 257/E23.069

(57) ABSTRACT

Provided is a feeding method for feeding conductive balls to the insides of through holes of a mask reliably and efficiently so as to match a fine pitch. In the feeding method, a head (300), which can move over the surface of a feeding mask (200) and which is caused to give a directivity to micro balls (340) by a squeezee (310) for rotating around a feed port (320) to be fed with the micro balls (340), is used to feed the micro balls (340) to the insides of a plurality of through holes (210) formed in the feeding mask (200). At this time, the head (300) is moved while being oscillated, to feed the micro balls (340) to the insides of the through holes (210) while improving the probability, on which the micro balls (340) meet the through holes (210) of the feeding mask (200).

### TECHNICAL FIELD

The present invention pertains to a ball mounter for mounting micro-balls onto BGA and CSP packages or other surface mount type semiconductor devices. In particular, the present invention pertains to a method of feeding micro-balls into a feeding mask.

### BACKGROUND TECHNOLOGY

In conjunction with the popularization of cell phones, portable computers, and other small size electronic devices, the demand for miniaturization and decreased thickness of the semiconductor devices mounted in said electronic devices has been on the rise. In order to meet this demand, BGA packages and CSP packages have been developed for practical applications.

BGA and CSP packages are semiconductor devices for surface mounting applications. That is, micro-balls for external connection terminals are mounted on a surface of the package substrate and connections are made with them. The methods for mounting said micro-balls include using a suction head and using a feeding mask. The method using a suction head is appropriate for mounting micro-balls of relatively large diameter, but it is inappropriate for mounting extremely small-diameter micro-balls for finer pitches because of problems with the processing tolerances of the suction head. On the other hand, the method using a feeding mask allows micro-processing by means of etching of the mask, so that it can be adopted appropriately in mounting extremely small micro-balls for fine pitches.

Patent Reference 1 has disclosed a method for mounting fine balls on a substrate or other workpiece by means of a feeding mask. On the other hand, Patent Reference 2 has disclosed a method for feeding solder balls in a feeding mask of a ball mounter. According to Patent Reference 2, as shown in FIG. 9, ball mounter (1) has the following parts: base (2) for placement of a semiconductor substrate or other workpiece (10), head (20) rotating in the horizontal direction on mask (11) layered on the surface of workpiece (10), motor (30) that drives head (20) to rotate, carrier (42) that drives head (20) and motor (30) to move along carrier shaft (41) in the x-direction of base (2), and shaft driving mechanism (43) that drives carrier shaft (41) to move in the y-direction of base (2).

FIG. 10(a) is a cross section of head (20) along the diameter of squeegee support (21). FIG. 10(b) is a drawing of the set of 6 squeegees (22) attached to the lower surface of squeegee support (21) as viewed from above squeegee support (21). Said head (20) has disk shaped squeegee support (21) and a set of 6 squeegees (22) arranged on the lower surface of squeegee support (21). Said squeegee support (21) is rotated by motor (30) via rotating shaft (25). Ball feeder (50) is mounted on carrier (42) for feeding solder balls (19), via the interior of rotating shaft (25), from the center of squeegee support (21) onto mask (11).

Each squeegee (22) has a constitution consisting of plural sweep members (23) arranged in the direction of movement of squeegees (22). Said sweep members (23) are driven to move so that solder balls (19) are pushed to flow on mask (11) in the movement direction; they sweep briskly, while solder balls (19) are inserted into the pattern of holes, etc. formed in mask (11).

Patent Reference 1: Japanese Kokai Patent Application No. 2004-327536

Patent Reference 2: Japanese Kokai Patent Application No. 2006-19741

### DISCLOSURE OF THE INVENTION

### Problems to be Solved by the Invention

FIG. 11 is a schematic top view illustrating the travel direction of the head in the ball mounter of the prior art. Here, plural through holes are formed in rectangular mask (60), and as shown in FIG. 11(a), head (62), which rotates in the horizontal direction, is driven to move from one end (64) to the other end (66) of mask (60) in the x-direction (longitudinal direction). Next, it is driven to move a prescribed distance in the y-direction (lateral direction) of the mask, and then to move from said other end (66) of the mask to said one end (64) in the x-direction. This reciprocating movement of head (62) is repeated multiple times according to the size of mask (62) [sic; (60)] and the number of through holes. Micro-balls (68) fed to the center of head (62) travel along trajectory P on mask (60) due to the movement in the x-direction and the rotation of head (62).

Said mask (60) is arranged facing the substrate where plural terminals are formed. As shown in FIG. 11(b), through holes (70) in mask (60) are formed in a two-dimensional pattern that is the same as the terminal pattern of the substrate. Hundreds of semiconductor devices are formed on the substrate, for example, and each semiconductor device has hundreds of external connection terminals formed on it, so that tens of thousands of through holes (70) are formed in mask (60). When head (60) [sic; (62)] is driven to move in a straight line in the x-direction while rotating in the horizontal direction, the probability that trajectories P of micro-balls (68) will encounter through holes (70) is not high. As a result, after scanning by head (62), there are through holes without micro-balls (68) inserted in them.

On the other hand, in order to increase the success rate of feeding micro-balls (68) into through holes (70), the number of micro-balls (68) fed onto the mask can be increased. In this case, however, the number of micro-balls failing to be inserted in through holes (70) increases, and the operation for recovering them is quite complicated. In addition, in order to increase the success rate of feeding the micro-balls, it is also possible to decrease the travel speed of head (62) in the x-direction. In this case, however, the time required for head (62) to scan the entire mask becomes very long, the feeding efficiency decreases, and the manufacturing throughput of semiconductor devices becomes much lower.

The purpose of the present invention is to solve the aforementioned problems of the prior art by providing a feeding method characterized by the fact that it can reliably feed electroconductive balls into through holes in a mask with high efficiency so that finer pitches can be realized.

### Means to Solve the Problems

The present invention provides a feeding method characterized by the following facts: it uses a head, which can be driven to move horizontally over the surface of a mask, and which feeds electroconductive balls from a feeding port and provides directionality to the electroconductive balls by means of a rotating member arranged surrounding said feeding port, to feed the electroconductive balls into the plural through holes formed in the mask; when the head is driven to move over the surface of the mask, vibration is applied to the head so that the electroconductive balls are fed into the through holes in the mask.

As a preferred scheme, the vibration direction of the head is orthogonal to the direction of the rotational axis of said rotating member, and it is nearly orthogonal to the travel direction of the head. Also, the head is driven to make reciprocating linear scanning movements.

As another feeding method, the present invention provides a feeding method characterized by the following facts: it uses a head, which can be driven to move horizontally over the surface of a mask, and which feeds electroconductive balls from a feeding port and provides directionality to the electroconductive balls by means of a rotating member arranged at the periphery of said feeding port, to feed the electroconductive balls into the plural through holes formed in the mask; while the head is driven to make zigzag movements over the surface of the mask, the electroconductive balls are fed into the through holes in the mask.

As another feeding method, the present invention provides a feeding method characterized by the following facts: it uses a head, which can be driven to move horizontally over the surface of a mask, and which feeds electroconductive balls from a feeding port and provides directionality to the electroconductive balls by means of rotating members arranged at the periphery of said feeding port, to feed the electroconductive balls into the plural through holes formed in the mask; plural rotating members are positioned eccentrically with respect to the center of the feeding port; when the head is driven to rotate, the electroconductive balls fed from said feeding port are subjected to variation by said plural rotating members, so that they are fed into the through structures [sic; through holes] in the mask.

With regard to the mask, for example, plural through holes are arranged as an array in the x-direction and Y-direction, with the pattern of the through holes matching the pattern of the external connection terminals of the semiconductor devices. Using said feeding mask makes it possible to form the bump electrodes of BGA and CSP.

### Effects of the Invention

According to the present invention, by moving the head while vibrating it, the space on the surface of the mask where the electroconductive balls are present is substantially expanded, so that the probability of the electroconductive balls finding the through holes in the mask is increased, and the electroconductive balls can be fed into the through holes more reliably and with higher efficiency.

In addition, by causing the head to move in zigzag fashion or making its rotation eccentric, it is possible to substantially expand the space where electroconductive balls are present on the surface of the mask, so that it is possible to feed the electroconductive balls into the through holes more reliably and with higher efficiency.

### PREFERRED EMBODIMENT OF THE PRESENT INVENTION

In the following, a preferred embodiment of the present invention will be explained in more detail with reference to figures.

### APPLICATION EXAMPLES

FIG. 1 is a schematic flow chart illustrating the semiconductor device pertaining to an application example of the present invention. In this application example, a BGA package is used as an example of a semiconductor device for surface mounting. First of all, plural semiconductor chips are mounted on a substrate (step S10), and the mounted semiconductor chips are encapsulated by means of a resin (step S11). Then, micro-balls are transferred onto the substrate terminal regions (electrode lands) (step S 12), and reflow is performed to make metal junctions between the micro-balls and terminal regions (step S 13). The substrate then is cut into individual semiconductor chips in a scribing operation (step S 14).

FIG. 2(a) is a plan view of the substrate having semiconductor chips mounted on it. FIG. 2(b) is a cross section illustrating one of the semiconductor chips mounted on the substrate. Substrate (100) is not restricted to the aforementioned constitution. A multilayer wiring substrate prepared by laminating an insulating layer and a wiring layer, or a film substrate can be used. For example, the outer configuration of substrate (100) has a longitudinal dimension of about 230 mm and a lateral dimension of about 62 mm. Semiconductor chips (102) are mounted on the surface of substrate (100) in a two-dimensional configuration. For example, assume that each block (104A) includes 5×5 semiconductor chips, and blocks (104B), (104C), (104D) are arranged in the longitudinal direction of substrate (100).

As shown in FIG. 2(b), each semiconductor chip (102) is anchored on substrate (100) by die-attach or another adhesive, and the electrodes formed on the surface of semiconductor chips (102) are connected to the wiring pattern on substrate (100) by means of bonding wires (106). As another scheme that can be adopted, semiconductor chips (102) can be mounted by means of the flip-chip mounting method wherein bump electrodes formed on the surface of the semiconductor chips are placed face down and connected to the wiring pattern of the substrate. The writing pattern formed on the surface of substrate (100) is electrically connected to plural terminal regions (108) (the portions shown in black in the figure) formed in an array configuration on the back surface of substrate (100) via internal wiring. As will be explained later, terminal regions (108) provide the regions for connecting the micro-balls to external connection terminals of the BGA package. For example, it is possible to connect tens to hundreds of micro-balls for each BGA package.

Also, individual semiconductor chips (102) on substrate (100) are encapsulated by means of resin (110). In this application example, each block consisting of 5×5 semiconductor chips is encapsulated as a unit. However, semiconductor chips (102) can also be individually encapsulated. For example, resin (110) on the surface of substrate (100) can be about 450 μm high, and substrate (100) can be about 240 μm thick.

FIG. 3(a) is a plan view of the feeding mask, and it shows an enlarged region of the mask corresponding to each semiconductor chip. Plural through holes (210) having the same pattern as that of terminal regions (108) of substrate (100) are formed in feeding mask (200). The diameter of each through hole (210) is larger by 10-20 μm than the diameter of the micro-ball.

As shown in FIG. 3(b) (indicating the feeding mask corresponding to one semiconductor chip), feeding mask (200) is arranged facing terminal regions (108) of substrate (100). As will be explained later, a head, which is driven to rotate while moving horizontally over the surface of feeding mask (200), is used to feed micro-balls (340) into through holes (210). For example, micro-balls (340) are solder balls or electroconductive metal balls prepared by forming a solder layer on the surface of a core made of copper or resin.

FIG. 4(a) is a side view of the head. FIG. 4(b) is a schematic plan view of the head as seen from the back. As shown in the figures, head (300) is a disk-shaped metal member, with plural squeegees (310) attached on the bottom. Micro-ball feeding port (320) for feeding micro-balls (340) is formed at the center of the head. Said micro-ball feeding port (320) is connected via tube (330) to a micro-ball feeder not shown in the figure.

For example, squeegees (310) can be formed from brushes arranged linearly. Each squeegee (310) is arranged at a prescribed inclination angle and at a prescribed distance from the center of micro-ball feeding port (320) at the center of head (300). When said head (300) is driven to rotate by a motor, not shown in the figure, squeegees (310) are driven to rotate together with it.

When the feeding of micro-balls into feeding mask (200) is performed, micro-balls (340) are fed from micro-ball feeding port (320). The micro-balls (340) fed in this case are given directionality corresponding to the travel direction of head (300) and by means of the rotation of squeegees (310). Said micro-balls (340) then fall into through holes (210) due to their own movement or from being swept by squeegees (310).

FIG. 5 is a block diagram illustrating schematically the constitution for driving the head. Here, the ball mounter has the following parts: X-direction driving part (410) that drives head (300) to move in the x-direction, Y-direction driving part (420) that drives head (300) in the y-direction, rotation driving part (430) that drives head (300) to rotate, vibration driving part (440) that applies vibration to head (300), and controller (450) that controls the various parts.

For example, X-direction driving part (410) contains a rack and pinion gear for moving head (300) in the x-direction and a stepping motor for driving it, and head (300) is driven to move in the x-direction. In the same way, said Y-direction driving part (420) moves head (300) in the Y-direction by means of a rack and pinion gear and a stepping motor. Rotation driving part (430) drives head (300) to rotate by means of a motor, for example. Said vibration driving part (440) uses a cam mechanism, a piezoelectric element or some other well-known means to apply vibration to head (300). It is preferred that vibration driving part (440) impart vibration in a direction orthogonal to the rotating shaft of head (300) and nearly perpendicular to the travel direction of head (300). For example, when head (300) is driven to move in the X-direction, vibration is applied in the Y-direction. Here the amplitude and frequency, etc., of the vibration can be selected appropriately according to the pitch of the through holes formed in the feeding mask, the travel velocity of the head, etc. For example, controller (450) contains a micro-controller, and it controls the scanning of head (300) according to a program stored in a memory.

FIG. 6 illustrates the first feeding method in this application example. As shown in FIG. 6(a), when feeding to feeding mask (200) is performed, head (300) is driven to scan in the x-direction from one end (202) to the other end (204) of feeding mask (200). After it is driven to move by a prescribed distance in the y-direction at said other end (204), it is driven to scan in the X-direction from said other end (204) to said one end (202). This scanning in the x-direction and Y-direction is performed repeatedly in multiple passes, so that the entirety of feeding mask (200) is scanned.

According to the first feeding method, vibration is applied to head (300) at the same time that head (300) is driven to scan. It is preferred that when head (300) is driven to move in the x-direction, vibration should be applied in the direction nearly perpendicular to said direction, that is, in the y-direction. Also, it is preferred that the amplitude of vibration be larger than the pitch of through holes (210). The various conditions of travel velocity, travel direction, vibration, etc., of head (300) are pre-stored in a memory, and the driving of head (300) is controlled by controller (450).

Said micro-balls (340) fed from micro-ball feeding port (320) of head (300) are given directionality which includes the vector in the x-direction of the head, the rotational vector of squeegees (310), and the vector that is a synthesis of the vibration vectors from the vibration. As a result, trajectory P1 of micro-balls (340) including the vibration component becomes a zigzag shape as shown in FIG. 6(a). By applying vibration to trajectory P1 of micro-balls (340), the space or range where micro-balls (340) are present becomes substantially larger than that for trajectory P in the prior art (see FIG. 11). This makes the probability that micro-balls (340) will encounter through holes (210) increase correspondingly. As a result, the success rate of inserting micro-balls (340) into through holes (210) of feeding mask (200) becomes very near 100%. At the same time, since the success rate of feeding is higher, it is also possible to increase the travel speed of head (300), and to shorten the time required for inserting the micro-balls.

As mentioned previously, the frequency, amplitude and direction of the vibration applied to the head can of course be adjusted appropriately according to factors such as the size of the micro-balls, the pitch of the through holes, the number of through holes, etc. Also, the vibration need not be regular, but can be applied intermittently, and the vibration conditions can be altered.

The second method of feeding this application example will be explained in the following. According to the second feeding method, instead of applying vibration to the head as was done in the first feeding method, the head is driven to travel along a zigzag path. For example, as shown in FIG. 7, when head (300) is driven to move in the x-direction, instead of moving linearly, the head moves in a sinusoidal meandering fashion (500) or follows a zigzag path. As a result, sinusoidal vectors or directionality can be realized for micro-balls (340) due to the meandering movement of head (300), so that the space where micro-balls (340) are present becomes wider, and the probability of encountering through holes (210) increases. As a result, the success rate of insertion of micro-balls (340) increases. Unlike in the first feeding method, the second feeding method requires no device for applying vibration to the head, so that the structure of the ball mounter can be simplified and the cost can be reduced. The first feeding method can of course be combined with the second feeding method. That is, it is possible to make the head wander while applying vibration to it.

The third method of feeding this application example will be explained in the following. According to the third feeding method, plural squeegees (310) are arranged eccentrically, and directionality is supplied to the micro-balls. For example, as shown in FIG. 8, the rotational center of head (600) is C1. This rotational center C1 nearly coincides with the center of micro-ball feeding port (320). On the other hand, the various squeegees (610) are at different distances from rotational center C1, and rotational center C2 of envelope circle (620) drawn to contact the ends of squeegees (610) is eccentric to rotational center C1. Because squeegees (610) are made eccentric, micro-balls (340) fed from micro-ball feeding port (320) are not given a uniform directionality with respect to rotational center C1. Initially, directionality is provided as if head (600) is in vibration. As a result, the probability that micro-balls (340) will encounter the through holes can be increased, and the success rate of insertion of micro-balls into the through holes is increased.

While preferred embodiments of the present invention have been explained in detail above, the present invention is not limited to the aforementioned embodiments. As long as the gist of the present invention described in the claims is observed, various modifications and changes can be made. For example, in said application examples, a BGA package is used as an example, but the present invention can also be adopted in CSP packages and other surface mount type semiconductor devices.

### INDUSTRIAL APPLICATION FIELD

The method of feeding electroconductive balls according to the present invention can be adopted in the semiconductor manufacturing devices for manufacturing surface mount type semiconductor devices.

### BRIEF DESCRIPTION OF THE FIGURES

FIG. 1 is a schematic flow chart illustrating the manufacturing operation of a semiconductor device in an application example of the present invention.

FIG. 2: FIG. 2(a) is a plan view illustrating an example of a substrate having semiconductor chips mounted on it. FIG. 2(b) is a cross section illustrating the case when a single semiconductor chip is encapsulated by resin on a substrate.

FIG. 3 is a plan view of the feeding mask.

FIG. 4: FIG. 4(a) is a side view of the head. FIG. 4(b) is a schematic plan view of the head as viewed from the back.

FIG. 5 is a block diagram illustrating the constitution for driving the head of the ball mounter.

FIG. 6 is a diagram illustrating a first feeding method in this application example.

FIG. 7 is a diagram illustrating a second feeding method in the present application example.

FIG. 8 is a diagram illustrating a third feeding method in the present application example.

FIG. 9 is a diagram illustrating a ball mounter that feeds solder balls into a feeding mask in the prior art.

FIG. 10: FIG. 10(a) is a cross section illustrating the head of the ball mounter in the prior art. FIG. 10(b) is a view of the squeegees through the head.

FIG. 11 is a diagram illustrating the problem of the feeding method in the prior art.

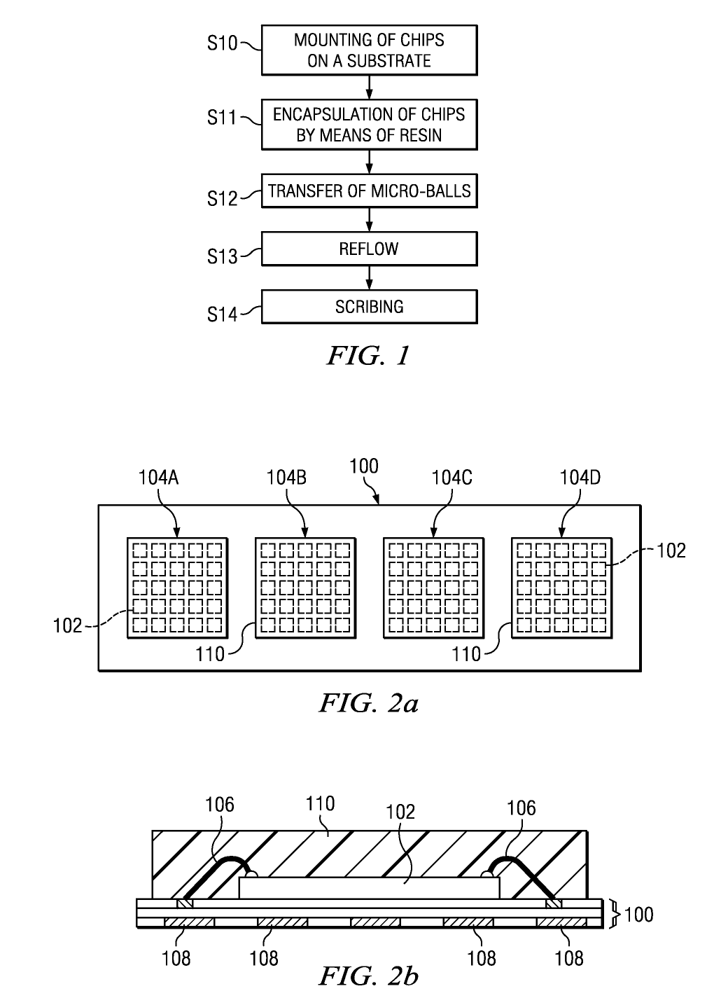

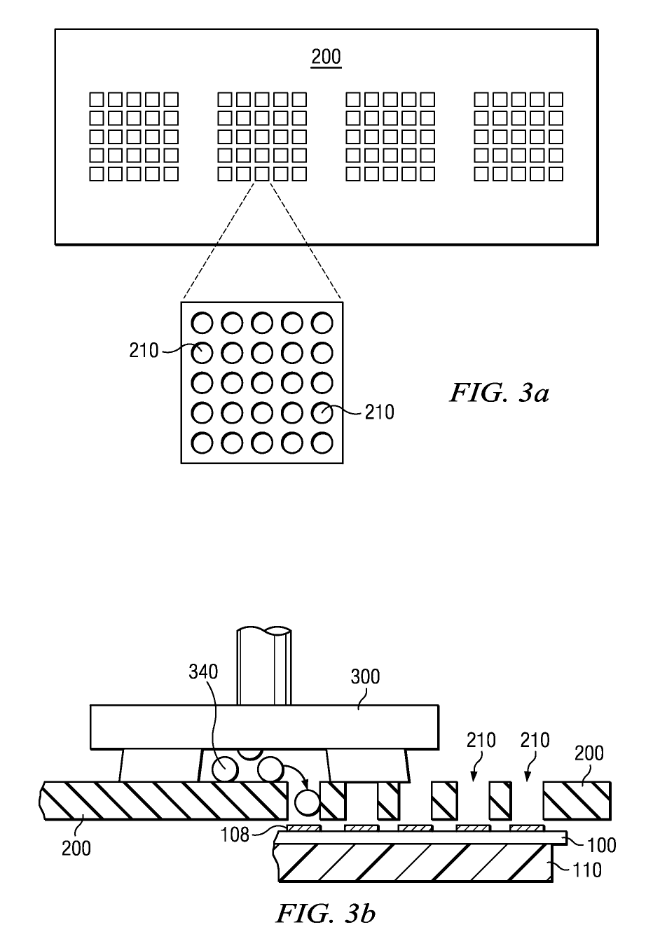

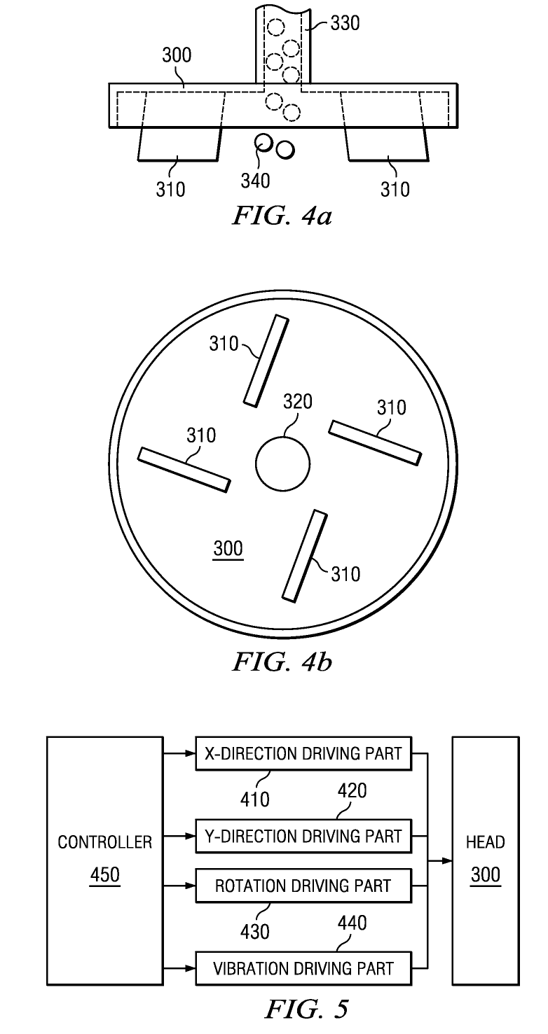

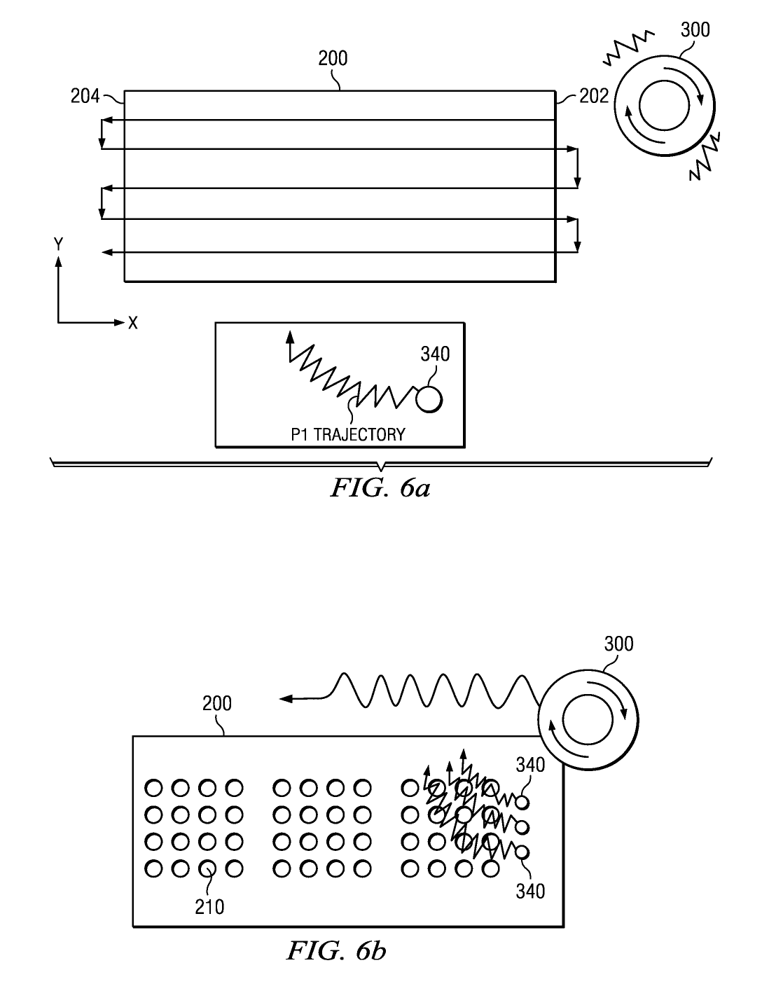

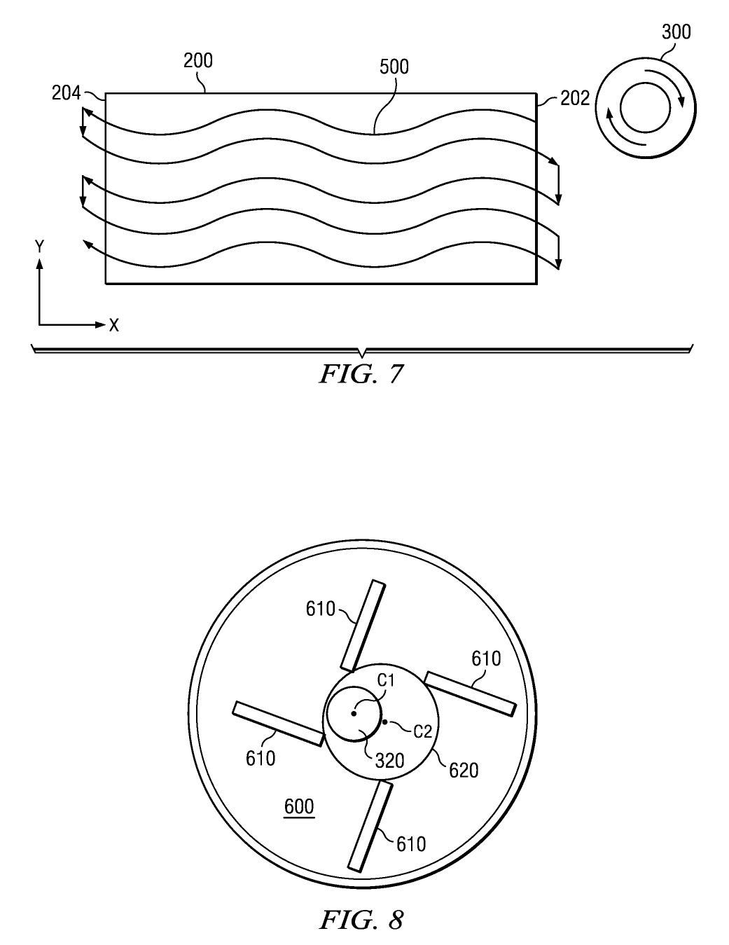

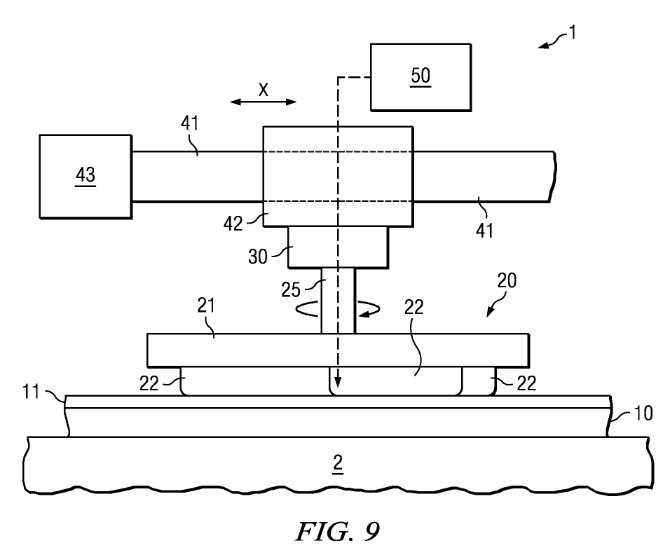

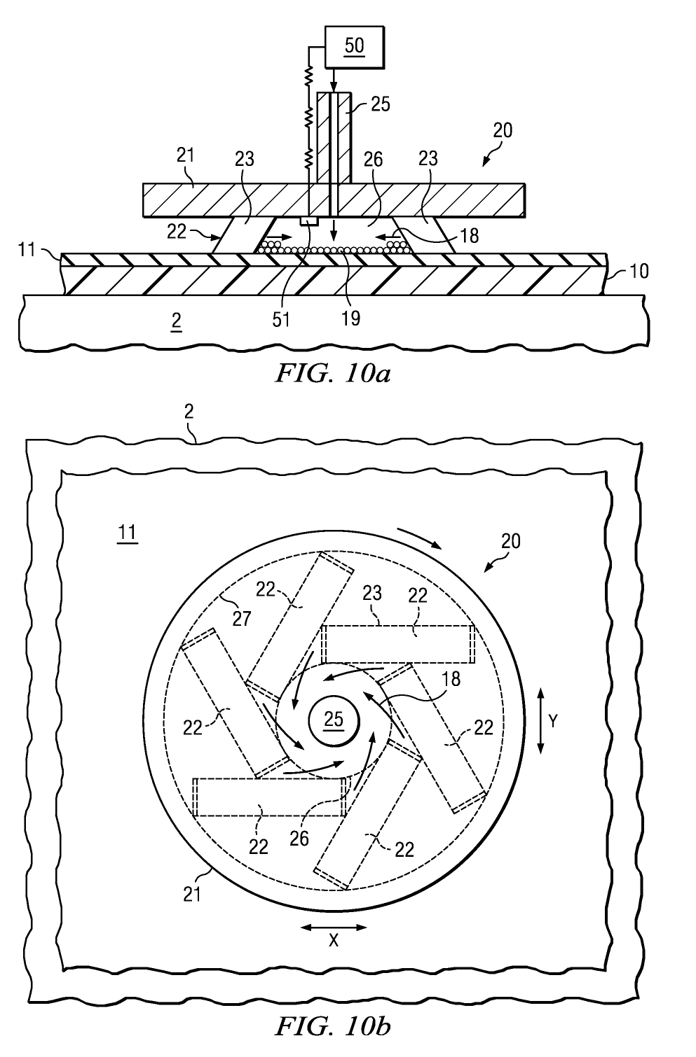

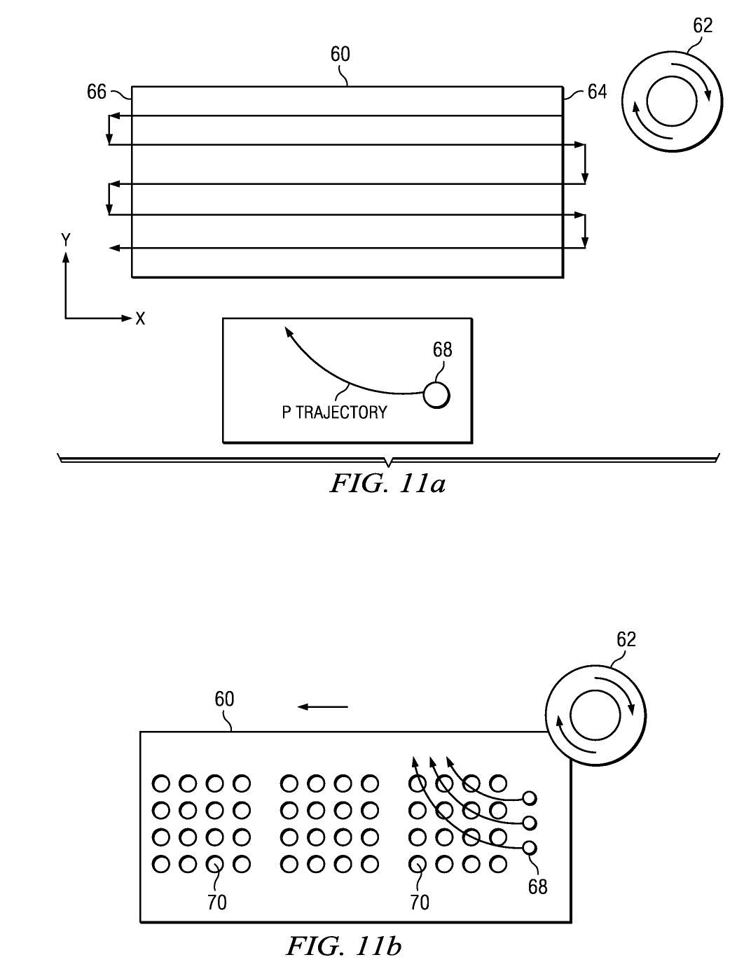

### Explanation of symbols

100 Substrate
102 Semiconductor chip
104A, 104B, 104C, 104D Block
106 Bonding wire
108 Terminal region
110 Encapsulating resin
200 Feeding mask
202 One end
204 Other end
210 Through hole
300, 600 Head
310, 610 Squeegee
320 Micro-ball feeding port
330 Tube
340 Micro-ball
500 Zigzag movement
620 Envelope circle

1. A feeding method characterized by the following facts: it uses a head, which can be driven to move horizontally over the surface of a mask, and which feeds electroconductive balls from a feeding port and provides directionality to the electroconductive balls by means of a rotating member arranged at the periphery of said feeding port, to feed the electroconductive balls into the plural through holes formed in the mask;
when the head is driven to move over the surface of the mask, vibration is applied on the head so that the electroconductive balls are fed into the through holes of the mask.

2. The feeding method described in claim 1 characterized by the fact that the vibration direction of the head is orthogonal to the direction of the rotational axis of said rotating member.

3. The feeding method described in claim 1 characterized by the fact that the vibration direction of said head is nearly orthogonal to the travel direction of the head.

4. The feeding method described in Claim 1 characterized by the fact that the head is driven to make reciprocating linear scanning movements.

5. A feeding method characterized by the following facts: it uses a head, which can be driven to move horizontally over the surface of a mask, and which feeds electroconductive balls from a feeding port and provides directionality to the electroconductive balls by means of a rotating member arranged at the periphery of said feeding port, to feed the electroconductive balls into the plural through holes formed in the mask;
while the head is driven to make zigzag movements over the surface of the mask, the electroconductive balls are fed into the through holes in the mask.

6. The feeding method described in claim 5 characterized by the fact that said head is driven to make reciprocating movement over the surface of the mask.

7. A feeding method characterized by the following facts: it uses a head, which can be driven to move horizontally over the surface of a mask, and which feeds electroconductive balls from a feeding port and provides directionality to the electroconductive balls by means of rotating members arranged at the periphery of said feeding port, to feed the electroconductive balls into the plural through holes formed in the mask;
plural rotating members are positioned eccentrically with respect to the center of the feeding port; when the head is driven to rotate, the electroconductive balls fed from said feeding port are subjected to variation by said plural rotating members, so that they are fed into the through structures [sic; through holes] in the mask.

8. The feeding method described in Claim 1 characterized by the fact that the mask has plural through holes arranged as an array in the x-direction and Y-direction.

9. A semiconductor device having electroconductive balls fed by means of the feeding method described in Claim 1.
